(19) United States
(12) Patent Application Publication
(10) Pub. No.: US 2026/0319034 A1
(43) Pub. Date: Oct. 15, 2026

(54) MAGNETIC RESONANCE IMAGING APPARATUS

(71) Applicant: CANON MEDICAL SYSTEMS CORPORATION, Otawara-shi (JP)

(72) Inventors: Daiki MIURA, Utsunomiya (JP); Kazuya OKAMOTO, Saitama (JP)

(73) Assignee: CANON MEDICAL SYSTEMS CORPORATION, Otawara-shi (JP)

(21) Appl. No.: 19/570,279

(22) Filed: Mar. 18, 2026

(30) Foreign Application Priority Data
Apr. 15, 2025 (JP) 2025-066637

(51) Int. Cl. G01R 33/34

(52) U.S. Cl. CPC G01R 33/34007

(57) ABSTRACT

A magnetic resonance imaging apparatus according to an embodiment includes a couch device, a power transmission coil, a detection unit, a movement mechanism, and a control unit. The couch device includes a couchtop on which a subject is placed. The power transmission coil is provided in the couch device and configured to wirelessly transmit power to a power reception coil provided in a reception coil unit including a reception coil. The reception coil unit is attached to the subject placed on the couchtop. The reception coil is configured to detect a magnetic resonance signal generated from the subject. The detection unit is configured to detect a current flowing in the power transmission coil. The movement mechanism is configured to move the power transmission coil. The control unit is configured to control the movement mechanism based on the current value detected by the detection unit in a state where a voltage is applied to the power transmission coil. The magnetic resonance signal detected by the reception coil is transmitted based on the power wirelessly transmitted from the power transmission coil to the power reception coil.

### CROSS-REFERENCE TO RELATED APPLICATIONS

This application is based upon and claims the benefit of priority from Japanese Patent Application No. 2025-066637, filed Apr. 15, 2025, the entire contents of which are incorporated herein by reference.

### FIELD

Embodiments described herein relate generally to a magnetic resonance imaging apparatus.

### BACKGROUND

In a magnetic resonance imaging apparatus (hereinafter referred to as an MRI apparatus), for example, power is supplied to a coil attached to a subject. Power supply is performed, for example, via a cable. However, in recent years, there has been a technique of transmitting power from a transmission-side coil to a reception-side coil by wireless power transmission. In transmitting power in this manner, a positional relationship between the transmission-side coil and the reception-side coil affects power transmission. Thus, the positional relationship between the transmission-side coil and the reception-side coil needs to be appropriately adjusted. However, since an installation position of the reception-side coil varies depending on a type of the reception-side coil, an imaging site of a subject, and the like, it is difficult to dispose the transmission-side coil at an appropriate position and effectively prepare for power supply.

### BRIEF DESCRIPTION OF THE DRAWINGS

FIG. 1 is a block diagram illustrating an overall configuration of a magnetic resonance imaging (MRI) apparatus according to a first embodiment;

FIG. 2 is a schematic cross-sectional view illustrating a state where a subject is fitted with a radio frequency (RF) coil device;

FIG. 3 is a schematic plan view illustrating the subject fitted with the RF coil device;

FIG. 4 is a graph illustrating an example of a relationship between a primary current value and a coupling coefficient between the primary coil and a secondary coil;

FIG. 5 is a flowchart illustrating an example of processing in the MRI apparatus;

FIG. 6 is a schematic cross-sectional view illustrating another state where the subject is fitted with the RF coil device;

FIG. 7 is a schematic cross-sectional view illustrating another state where the subject is fitted with the RF coil device;

FIG. 8 is a schematic plan view illustrating the subject fitted with the RF coil device according to a second embodiment;

FIG. 9 is a schematic plan view illustrating the subject fitted with the RF coil device according to a third embodiment;

FIG. 10 is a schematic cross-sectional view illustrating a state where the subject is fitted with the RF coil device according to a fourth embodiment; and

FIG. 11 is a schematic plan view illustrating the subject fitted with the RF coil device according to the fourth embodiment.

### DETAILED DESCRIPTION

A magnetic resonance imaging apparatus according to an embodiment includes a couch device, a power transmission coil, a detection unit, a movement mechanism, and a control unit. The couch device includes a couchtop on which a subject is placed. The power transmission coil is provided in the couch device and configured to wirelessly transmit power to a power reception coil provided in a reception coil unit including a reception coil. The reception coil unit is attached to the subject placed on the couchtop. The reception coil is configured to detect a magnetic resonance signal generated from the subject. The detection unit is configured to detect a current flowing in the power transmission coil. The movement mechanism is configured to move the power transmission coil. The control unit is configured to control the movement mechanism based on the current value detected by the detection unit in a state where a voltage is applied to the power transmission coil. The magnetic resonance signal detected by the reception coil is transmitted based on the power wirelessly transmitted from the power transmission coil to the power reception coil.

Various Embodiments will be described hereinafter with reference to the accompanying drawings.

### First Embodiment

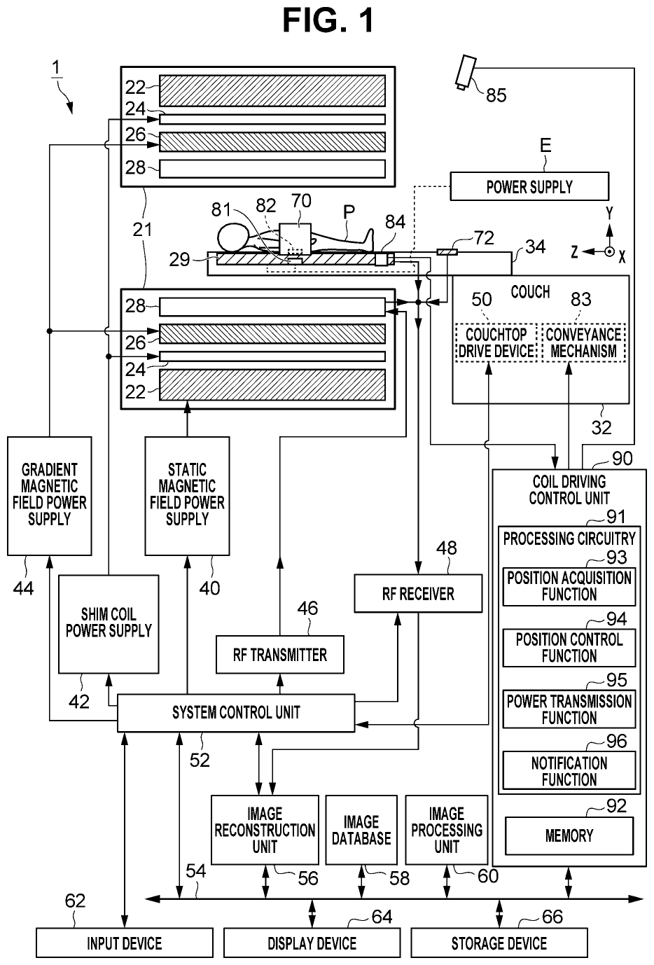

FIG. 1 is a block diagram illustrating an overall configuration of a magnetic resonance imaging (MRI) apparatus 1 according to a first embodiment. As illustrated in FIG. 1, the MRI apparatus 1 includes a gantry 21, a couch 32, and a couchtop 34. A subject P is placed on the couchtop 34. The gantry 21 (including devices and the like house in the gantry 21), the couch 32, and the couchtop 34 constitute an example of a couch device.

The MRI apparatus 1 includes, in the gantry 21 formed, for example, in a cylindrical shape, a static magnetic field magnet 22, a shim coil 24, a gradient magnetic field coil 26, and a transmission radio frequency (RF) coil 28. The gantry 21 corresponds to two thick frames in FIG. 1. Each of the static magnetic field magnet 22 and the shim coil 24 has, for example, a cylindrical shape, and the shim coil 24 is disposed coaxially with the static magnetic field magnet 22 inside the static magnetic field magnet 22.

In this configuration, as an example, an X-axis, a Y-axis, and a Z-axis that are orthogonal to one another in an apparatus coordinate system are defined as follows. First, assume that the static magnetic field magnet 22 and the shim coil 24 are disposed such that their axial directions are orthogonal to a vertical direction, and each of the axial directions of the static magnetic field magnet 22 and the shim coil 24 is a Z-axis direction. Additionally, assume that the vertical direction is a Y-axis direction, and the couchtop 34 is disposed such that a normal direction of a top surface of the couchtop 34 is the Y-axis direction.

The MRI apparatus 1 includes, as a control side thereof, a static magnetic field power supply 40, a shim coil power supply 42, a gradient magnetic field power supply 44, a radio frequency (RF) transmitter 46, an RF receiver 48, a couchtop drive device 50, a system control unit 52, a system bus 54, an image reconstruction unit 56, an image database 58, an image processing unit 60, an input device 62, a display device 64, and a storage device 66. The couchtop drive device 50 is disposed within the couch 32.

The static magnetic field magnet 22 causes a static magnetic field to be formed in an imaging space by a current supplied from the static magnetic field power supply 40. The above-mentioned imaging space refers to, for example, a space inside the gantry 21 in which the subject P is placed and to which a static magnetic field is applied. The static magnetic field magnet 22 is constituted by a superconducting coil in many cases. The static magnetic field magnet 22 is connected to the static magnetic field power supply 40 and supplied with a current when being excited, and is generally brought into a non-connected state once excitation has been completed. The static magnetic field magnet 22 may be constituted by a permanent magnet without providing the static magnetic field power supply 40.

The shim coil 24 is connected to the shim coil power supply 42 and homogenizes the static magnetic field by a current supplied from the shim coil power supply 42. The gradient magnetic field coil 26 is formed, for example, in a cylindrical shape inside the static magnetic field magnet 22. The gradient magnetic field coil 26 forms a gradient magnetic field Gx in an X-axis direction, a gradient magnetic field Gy in the Y-axis direction, and a gradient magnetic field Gz in the Z-axis direction in an imaging region by a current supplied from the gradient magnetic field power supply 44. By combining the gradient magnetic fields Gx, Gy, and Gz in the three axial directions of the apparatus coordinate system, it is possible to freely set directions of a slice-select direction gradient magnetic field Gss, a phase-encoding direction gradient magnetic field Gpe, and a readout direction (frequency-encoding direction) gradient magnetic field Gro as logical axes.

The imaging region is, for example, a region corresponding to at least part of a range for collecting magnetic resonance signals (hereinafter referred to as MR signals) to be used to generate one image or one set of images and is a region that becomes an image. For example, in a case where MR signals are collected from a range wider than the region to be imaged to prevent aliasing artifacts, the imaging region is a part of the range for collecting MR signals. Meanwhile, there is a case where the entire range for collecting MR signals becomes an image and the range for collecting MR signals and the imaging region coincide with each other. Additionally, the above-mentioned “one set of images” refers to a plurality of images in a case where MR signals for a plurality of images are collectively collected in one pulse sequence, such as in multi-slice imaging.

Based on control information input from the system control unit 52, the RF transmitter 46 generates an RF pulse (RF current pulse) at a Larmor frequency to cause nuclear magnetic resonance, and transmits the RF pulse to the transmission RF coil 28. Upon receiving the RF pulse from the RF transmitter 46, the transmission RF coil 28 transmits this RF pulse to the subject P. The transmission RF coil 28 includes a whole body coil (not illustrated) that is built into the gantry 21 and that performs both transmission and reception of RF pulses.

A reception RF coil 29 is disposed inside the couchtop 34. The reception RF coil 29 detects an MR signal generated when a nuclear spin in the subject P is excited by the RF pulse. The reception RF coil 29 transmits the detected MR signal to the RF receiver 48. The reception RF coil 29 is supplied with power from a power supply E.

The subject P is fitted with an RF coil device 70. The RF coil device 70 is, for example, an attachable local coil for receiving MR signals. The RF coil device 70 is described here as a part of the MRI apparatus 1 as an example, but may be regarded as a separate device from the MRI apparatus 1.

The RF coil device 70 includes, for example, a mounting part 71, a plurality of coil elements 72, and an MR signal transmitter 73. The RF coil device 70 is attached to the subject P placed on the couchtop 34 and includes a reception coil. The mounting part 71 is made of, for example, fabric, and wraps the subject P in a circumferential direction and is attached to the subject P.

The plurality of coil elements 72 is attached to the mounting part 71 around the body of the subject P at intervals. Each coil element 72 detects an MR signal generated in the subject P by an RF pulse transmitted from the RF transmitter 46. The coil element 72 detects the MR signal generated from the subject P. The RF coil device 70 is an example of a reception coil unit. The coil element 72 is an example of a reception coil.

The MR signal transmitter 73 is electrically connected to the plurality of coil elements 72. The MR signal transmitter 73 transmits MR signals detected by the coil elements 72 to the RF receiver 48 via wireless communication. A plurality of RF coil devices may be attached to the subject P. The MR signals detected by the coil elements 72 are transmitted based on power wirelessly transmitted from a primary coil 81 to a secondary coil 82.

The RF receiver 48 performs predetermined signal processing on the received MR signals to generate complex data of the digitized MR signals (hereinafter referred to as raw data of the MR signals). The RF receiver 48 inputs the generated raw data of the MR signals to the image reconstruction unit 56.

The system control unit 52 performs system control of the entire MRI apparatus 1 via wiring such as the system bus 54 to perform an imaging operation and display an image after imaging. The system control unit 52 drives the gradient magnetic field power supply 44, the RF transmitter 46, and the RF receiver 48 in accordance with a stored predetermined sequence, and thereby generates the gradient magnetic fields Gx, Gy, and Gz, and RF pulses. The system control unit 52 controls the couchtop drive device 50 to move the couchtop 34 in the Z-axis direction and to insert or withdraw the couchtop 34 into or from the imaging space inside the gantry 21.

The system control unit 52 controls the couchtop drive device 50 to change the height of the couch 32, thereby enabling the couchtop 34 to be raised and lowered in the Y-axis direction. The system control unit 52 controls the position of the couchtop 34 in this manner to position an imaging site of the subject P on the couchtop 34 at the center of a magnetic field within the imaging space.

The system control unit 52 also functions as an imaging condition setting unit. More specifically, the system control unit 52 sets imaging conditions for a main scan based on information regarding the subject P and some imaging conditions that are input by an operator to the input device 62. To this end, the system control unit 52 displays setting screen information regarding the imaging conditions on the display device 64.

The above-mentioned imaging conditions refer to, for example, which type of pulse sequence is used, under what conditions RF pulses and the like are transmitted, and under what conditions MR signals are collected from the subject P. Examples of the imaging conditions include an imaging region as positional information in the imaging space, an imaging site, a type of pulse sequence such as parallel imaging, a type of RF coil device to be used, the number of slices, and an interval between the slices.

The above-mentioned imaging site refers to, for example, which part of the subject P, such as the head, chest, or abdomen, is to be imaged as the imaging region. Assume that the above-mentioned “main scan” refers to a scan for capturing an intended diagnostic image such as a proton density weighted image, and does not include a scan for collecting MR signals for an image for positioning or a scan for calibration.

Assume that a scan refers to an operation of collecting MR signals and does not include image reconstruction. The scan for calibration refers to, for example, a scan that is performed separately from a main scan to determine a yet-to-be-determined imaging condition among the imaging conditions for the main scan or a condition and data to be used at the time of reconstructing an image after the main scan. A pre-scan, which will be described below, refers to a scan to be performed before the main scan during the scan for calibration.

The input device 62 provides the operator with a function of setting the imaging conditions and an image processing condition. In the present specification, the input device 62 (input interface) is not limited to a device including a physical operating component such as a mouse or a keyboard. Examples of the input interface also include electrical signal processing circuitry that receives an electrical signal corresponding to an input operation from an external input device provided separately from the MRI apparatus 1 and that outputs the electrical signal to control circuitry.

The image reconstruction unit 56 converts the raw data of the MR signal input from the RF receiver 48 into, for example, matrix data based on the number of phase encode steps and the number of frequency encode steps, and stores the matrix data as k-space data. The k-space refers to the frequency space (Fourier space).

The image reconstruction unit 56 performs image reconstruction processing including two-dimensional Fourier transform on the k-space data to generate image data regarding the subject P. The image reconstruction unit 56 stores the generated image data in the image database 58.

The image processing unit 60 retrieves image data from the image database 58, performs predetermined image processing on the image data, and stores, in the storage device 66, the image data that has undergone the image processing as image data for display.

The storage device 66 attaches, to the image data for display, imaging conditions used to generate the image data for display, information regarding the subject P (patient information), and the like as ancillary information, and stores the image data for display. Under control of the system control unit 52, the display device 64 displays a screen for setting imaging conditions for a main scan, an image represented by image data generated by imaging, and the like.

The couchtop 34 of the couch 32 is equipped with a power transmission coil (hereinafter referred to as primary coil) 81, and the RF coil device 70 is equipped with a power reception coil (hereinafter referred to as secondary coil) 82. The couchtop 34 is provided with an ammeter 84 that detects a current value of a current flowing in the primary coil 81.

The ammeter 84 transmits the detected current value to the system control unit 52. The primary coil 81 is provided, for example, on the opposite side of the subject P with respect to the couchtop 34, for example, on the back side of the couchtop 34. The primary coil 81 may be provided at a position on the couch 32 other than the couchtop 34. The ammeter 84 is an example of a detection unit.

The power supply E is connected to the primary coil 81, and supplies power to the primary coil 81. The primary coil 81 wirelessly transfers the supplied power to the secondary coil 82. The secondary coil 82 receives the power transmitted from the primary coil 81. The power received by the secondary coil 82 is utilized as power to operate the MR signal transmitter 73 or the like of the RF coil device 70. A conveyance mechanism 83 conveys the mounted primary coil 81 along a horizontal plane to move the primary coil 81. The conveyance mechanism 83 is an example of a movement mechanism. The ammeter 84 transmits the detected current value to a coil driving control unit 90.

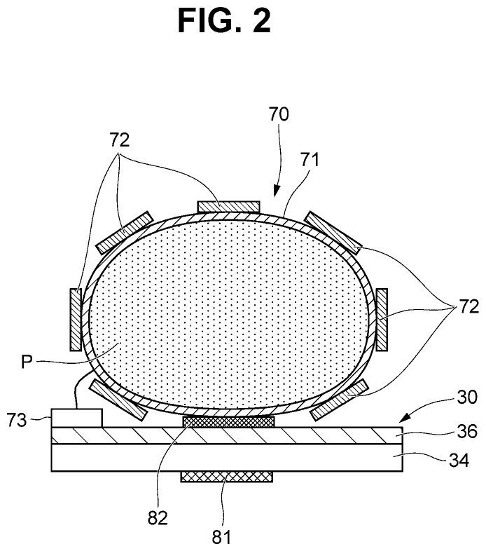

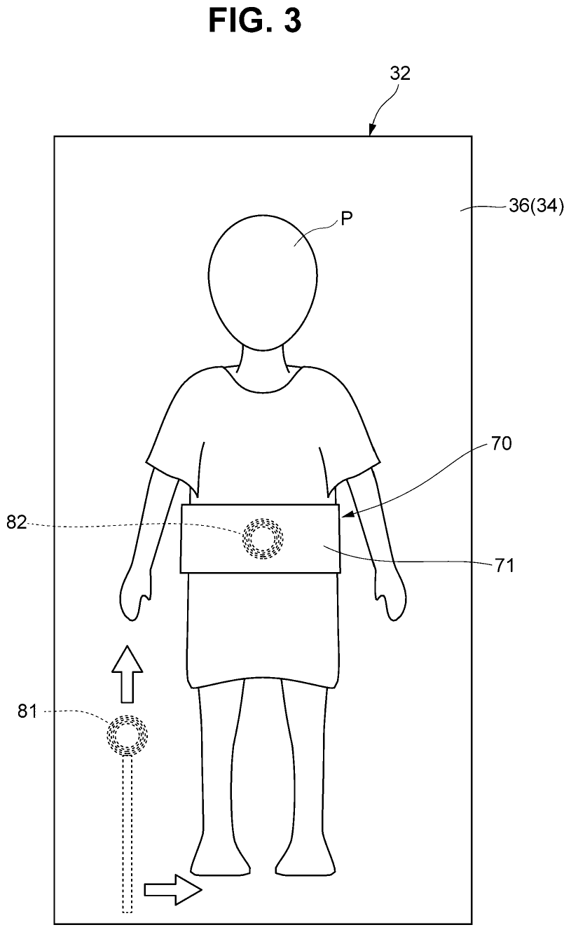

The subject P, to be examined with the MRI apparatus 1, is fitted with the RF coil device 70 and placed on the couchtop 34 of the couch 32. A description is now provided of a relationship among the RF coil device 70 attached to the subject P placed on the couchtop 34, the primary coil 81, and the secondary coil 82. FIG. 2 is a schematic cross-sectional view illustrating a state where the subject P is fitted with the RF coil device 70. FIG. 3 is a schematic plan view illustrating the subject P fitted with the RF coil device 70. FIGS. 2 and 3 each illustrate a state where the subject P is placed on the couchtop 34.

For example, a pad 36 is laid on the couchtop 34 on which the subject P is placed. The subject P is placed on the pad 36 and set on the couchtop 34. When the subject P takes a posture for MR imaging, the RF coil device 70 is attached to the subject P such that the secondary coil 82 is disposed in the vicinity of the couchtop 34. In the example illustrated in FIG. 2, the secondary coil 82 is disposed immediately above the couchtop 34.

The primary coil 81 is provided on the underside of the couchtop 34. The primary coil 81 is mounted on the conveyance mechanism 83 and is movable on the underside of the couchtop 34 in a planar direction as illustrated in FIG. 3. The primary coil 81 is movable to any position, for example, either a position outside the subject P in a plan view or a position overlapping the subject P. Under control of the coil driving control unit 90, the conveyance mechanism 83 moves the primary coil 81 to any position on the underside of the couchtop 34.

The coil driving control unit 90 controls the conveyance mechanism 83 based on the current value detected by the ammeter 84 in a state where a voltage is applied to the primary coil 81. The coil driving control unit 90 controls the conveyance mechanism 83, for example, such that the primary coil 81 is located at a position at which the current value detected by the ammeter 84 in the state where a voltage is applied to the primary coil 81 is more than a predetermined value, for example, a threshold THi to be described below. The coil driving control unit 90 is an example of a control unit.

A camera 85 is provided on the ceiling of an examination room in which the MRI apparatus 1 is installed. The camera 85 is an optical camera that captures an image of a region in the examination room including the couchtop 34 of the couch 32 on which the subject P is placed. The region whose image is captured by the camera 85 includes the subject P placed on the couchtop 34 and the RF coil device 70 attached to the subject P. The camera 85 transmits a captured image of the inside of the examination room (hereinafter referred to as an indoor image) to the coil driving control unit 90.

To the system bus 54, the coil driving control unit 90 is further connected. The coil driving control unit 90 includes, for example, processing circuitry 91 and a memory 92. The processing circuitry 91 includes, for example, a position acquisition function 93, a position control function 94, a power transmission function 95, and a notification function 96. The coil driving control unit 90 may be built into the system control unit 52.

The processing circuitry 91 performs, for example, drive control of the conveyance mechanism 83 to control the position of the primary coil 81. The processing circuitry 91 grasps coordinates of the position to which the primary coil 81 is conveyed by the conveyance mechanism 83 as coordinates of the position of the primary coil 81. The processing circuitry 91 stores a history of the coordinates of the position of the primary coil 81 in the memory 92.

The processing circuitry 91 implements these functions by executing programs stored in the memory (storage circuitry) 92, for example, by a hardware processor. The hardware processor refers to circuitry such as a central processing unit (CPU), a graphics processing unit (GPU), an application specific integrated circuit (ASIC), or a programmable logic device (for example, a simple programmable logic device (SPLD), a complex programmable logic device (CPLD), or a field programmable gate array (FPGA)).

Instead of storing the programs in the memory 92, the programs may be directly built into circuitry of the hardware processor. In this case, the hardware processor reads and executes the programs built into the circuitry to implement the functions. The hardware processor is not limited to a hardware processor configured as a single piece of circuitry, and may also be a hardware processor configured as one hardware processor by combining a plurality of independent pieces of circuitry to implement the functions. Alternatively, each function may be implemented by integrating a plurality of constituent elements into one hardware processor.

The memory 92 stores control information necessary for driving the gradient magnetic field power supply 44, the RF transmitter 46, and the RF receiver 48. The control information mentioned herein refers to, for example, sequence information that describes operation control information such as the intensity, application time, and application timing of a pulse current to be applied to the gradient magnetic field power supply 44.

The position acquisition function 93 reads out positional coordinates of the primary coil 81 stored in the memory 92, and acquires the position of the primary coil 81. The position acquisition function 93 acquires the position of the secondary coil 82 based on an indoor image transmitted from the camera 85.

The position acquisition function 93 acquires a distance between the primary coil 81 and the RF coil device 70 based on an image obtained by the camera 85 that captures an image of the couchtop 34. The position acquisition function 93 performs image processing on the indoor image transmitted from the camera 85 to extract the RF coil device 70. The position acquisition function 93 acquires the position of the secondary coil 82 with respect to the couchtop 34 from the shape of the extracted RF coil device 70 or the like.

The secondary coil 82 is provided in the RF coil device 70 and is often not directly visible in the indoor image. The position acquisition function 93 estimates and acquires the position of the secondary coil 82 based on, for example, the position, orientation, shape (shape deformed by the posture of the subject P), and the like of the RF coil device 70. The RF coil device 70 serves as an index for estimating the position of the secondary coil 82. The position acquisition function 93 is an example of a position acquisition unit.

While the positions of the primary coil 81 and the secondary coil 82, which are acquired by the position acquisition function 93, can be easily detected, the position of the secondary coil 82 is not so accurate. The position acquisition function 93 uses the easily detected positions of the primary coil 81 and the secondary coil 82 to grasp a rough, relative positional relationship between the positions of the primary coil 81 and the secondary coil 82, for example, whether the position of the primary coil 81 is within a control region. The control region refers to, for example, a range in which the primary coil 81 and the secondary coil 82 come close to each other and a current value of the primary coil 81 becomes large, for example, equal to or greater than a predetermined current value, or a range in which a distance between the primary coil 81 and the secondary coil 82 becomes equal to or less than a predetermined distance. Subsequently, the position control function 94 moves the primary coil 81 to a position where efficiency of transmission of power from the primary coil 81 to the secondary coil 82 is high.

The position control function 94 controls the conveyance mechanism 83 so that the distance between the primary coil 81 and the RF coil device 70, which is acquired by the position acquisition function 93, is equal to or less than the predetermined distance. The position control function 94 controls the conveyance mechanism 83 so that, for example, in a state where the distance between the primary coil 81 and the RF coil device 70 is equal to or less than the predetermined distance, the primary coil 81 is located at a position where the current value detected by the ammeter 84 in the state where a voltage is applied to the primary coil 81 is greater than the predetermined value.

The position control function 94, for example, identifies a control start position to control the position of the primary coil 81. In a case where the position of the primary coil 81 acquired by the position acquisition function 93 is within the control region, the position control function 94 sets the position as the control start position. In a case where the position of the primary coil 81 is not within the control region, the position control function 94 controls the conveyance mechanism 83 to move the primary coil 81 to be within the control region. The position control function 94 sets the position of the primary coil 81 at the time when it is determined that the primary coil 81 has entered the control region as the control start position.

The position control function 94 acquires the current value of a current flowing in the primary coil 81 that is detected by the ammeter 84 when a constant voltage is applied to the primary coil 81 within the control region. The position control function 94 controls the conveyance mechanism 83 to search for a position of the primary coil 81 where the current value detected by the ammeter 84 becomes large while moving the position of the primary coil 81, and then moves the primary coil 81.

When the current value transmitted from the ammeter 84 exceeds a threshold, the position control function 94 stops the movement of the primary coil 81 by the conveyance mechanism 83. The threshold to be used for determination is a current value larger than the predetermined current value used for determining whether the position of the primary coil 81 is within the control region. The threshold to be used for determination may be appropriately determined, and may be determined, for example, based on a coupling coefficient between the primary coil 81 and the secondary coil 82 (hereinafter referred to as an effective coupling coefficient). The position control function 94 is an example of a position control unit.

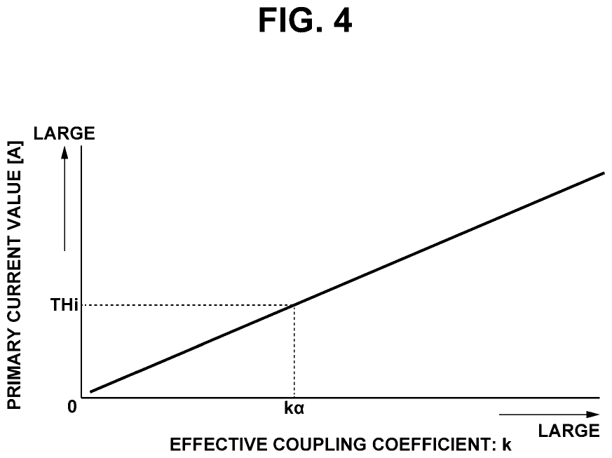

As the effective coupling coefficient becomes larger, power supply efficiency when power is supplied from the primary coil 81 to the secondary coil 82 becomes higher. The effective coupling coefficient is in a relative relationship with a current value of a current flowing in the primary coil 81 (hereinafter referred to as a primary current value) and a current value of a current flowing in the secondary coil 82. FIG. 4 is a graph illustrating an example of a relationship between the primary current value and an effective coupling coefficient k.

As the primary coil 81 is brought closer to the secondary coil 82, the effective coupling coefficient k becomes larger, and the primary current value also becomes larger with the increase of the effective coupling coefficient k. For example, when a lower limit value of the effective coupling coefficient k for efficiently preparing for power supply is defined as a lower limit coupling coefficient kα, the primary current value corresponding to the lower limit coupling coefficient kα is the threshold THi. When the primary current value transmitted from the ammeter 84 exceeds the threshold THi, the position control function 94 stops the movement of the primary coil 81 by the conveyance mechanism 83. The lower limit coupling coefficient kα may be, for example, any value from 0.1 to 0.3.

The power transmission function 95 supplies power from the power supply E to the primary coil 81 located at the position where the primary current value exceeds the threshold THi. As a result, power is transmitted from the primary coil 81 to the secondary coil 82 by wireless power supply.

If a state where the current value detected by the ammeter 84 in the state where a voltage is applied to the primary coil 81 is less than a predetermined value continues for a predetermined time, the notification function 96 issues a notification indicating that a setting of the RF coil device 70 for the subject P is to be performed. The notification function 96, for example, measures time after the current value detected by the ammeter 84 becomes less than the predetermined value until it exceeds the predetermined value.

When the measured time reaches a predetermined time, the notification function 96 issues the notification indicating that the setting of the RF coil device 70 for the subject P is to be performed, for example, issues an instruction for resetting. The notification indicating that the setting is to be performed may be issued in a mode other than a mode of issuing the instruction for resetting. The notification function 96 is an example of a notification unit.

Subsequently, a procedure for examining the subject P using the MRI apparatus 1 will be described. In the MRI apparatus 1, after the subject P fitted with the RF coil device 70 is placed on the couchtop 34, processing is executed by the coil driving control unit 90. In a case where the subject P is examined using the MRI apparatus 1, first, the RF coil device 70 is attached to the subject P by a user such as a doctor or a technician. The RF coil device 70 is attached to the subject P, for example, so as to cover an examination site of the subject P. Subsequently, the user places the subject P on the couchtop 34 of the couch 32.

Subsequently, the user performs a setting in which the posture of the subject P placed on the couchtop 34 is adjusted according to the imaging site or the like. The RF coil device 70 is attached to the subject P in consideration of the posture of the subject P at the time of imaging. For example, when the subject P is placed in a posture according to the imaging site, the RF coil device 70 is attached to the subject P so that the secondary coil 82 provided in the RF coil device 70 becomes close to the couchtop 34. In the MRI apparatus 1, after the subject P fitted with the RF coil device 70 is placed on the couchtop 34 and the setting for adjusting the posture is performed, processing is executed by the coil driving control unit 90.

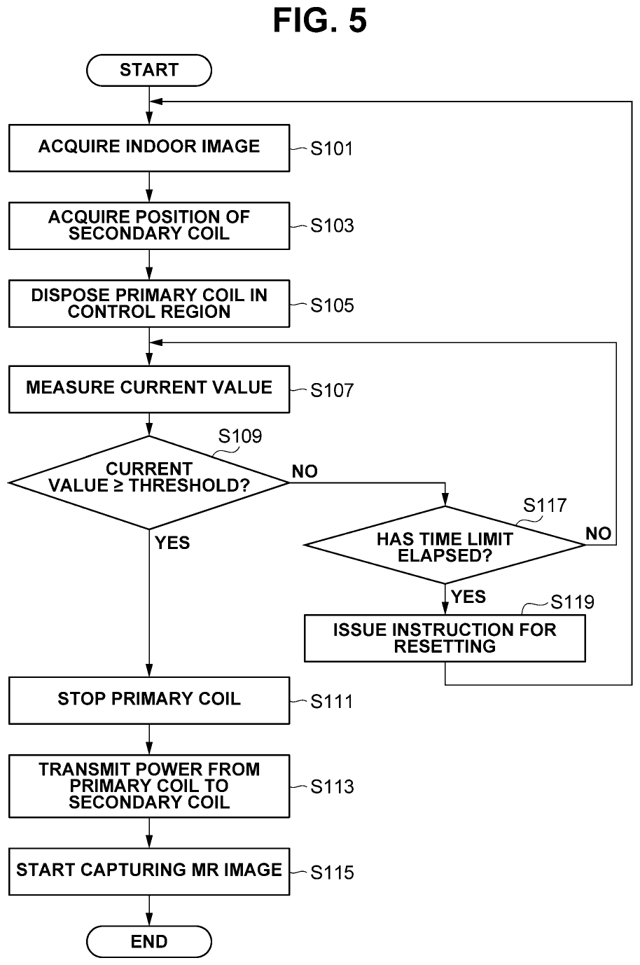

FIG. 5 is a flowchart illustrating an example of processing in the MRI apparatus 1. In FIG. 5, a procedure for adjusting the position of the primary coil 81 is illustrated. The processing illustrated in FIG. 5 is started and executed by the coil driving control unit 90 when the user inputs an instruction for starting to capture an MR image after the subject P is placed on the couchtop 34.

In step S101, the coil driving control unit 90 first uses the position acquisition function 93 to acquire an indoor image captured by the camera 85 and transmitted from the camera 85. Subsequently, in step S103, the position acquisition function 93 performs image processing or the like on the acquired indoor image to extract the subject P and the RF coil device 70, and estimates and acquires the position of the secondary coil 82 based on the posture of the extracted subject P, the position of the extracted RF coil device 70, and the like.

Subsequently, in step S105, the position control function 94 disposes the primary coil 81 in the control region in the vicinity of the acquired position of the secondary coil 82. The position control function 94 compares the acquired position of the primary coil 81 and the acquired position of the secondary coil 82 to determine whether the primary coil 81 is within the control region. In a case where the primary coil 81 is within the control region, the processing directly proceeds to step S107. In a case where the primary coil 81 is outside the control region, the conveyance mechanism 83 moves the primary coil 81 into the control region.

Subsequently, in step S107, the position control function 94 acquires a value of a current flowing in the primary coil 81 and measured by the ammeter 84. Subsequently, in step S109, the position control function 94 determines whether the value of the current acquired in step S107 is the threshold THi or more.

In a case where the position control function 94 determines that the current value acquired in step S107 is equal to or greater than the threshold THi (YES in step S109), the processing proceeds to step S111. In step S111, the position control function 94 ends the movement of the primary coil 81 by the conveyance mechanism 83 and stops the primary coil 81. Then, in step S113, the power transmission function 95 transmit power from the primary coil 81 to the secondary coil 82. Then, in step S115, capturing of an MR image is started. In this way, the processing illustrated in FIG. 5 ends.

In a case where the position control function 94 determines that the current value acquired in step S107 is not equal to or greater than the threshold THi (is less than the threshold THi) (NO in step S109), the processing proceeds to step S117. In step S117, the position control function 94 determines whether a time limit has elapsed. In a case where the position control function 94 determines that the time limit has not elapsed (NO in step S117), the processing returns to step S107, in which the position control function 94 continues measuring of the current value until the time limit elapses while moving the primary coil 81.

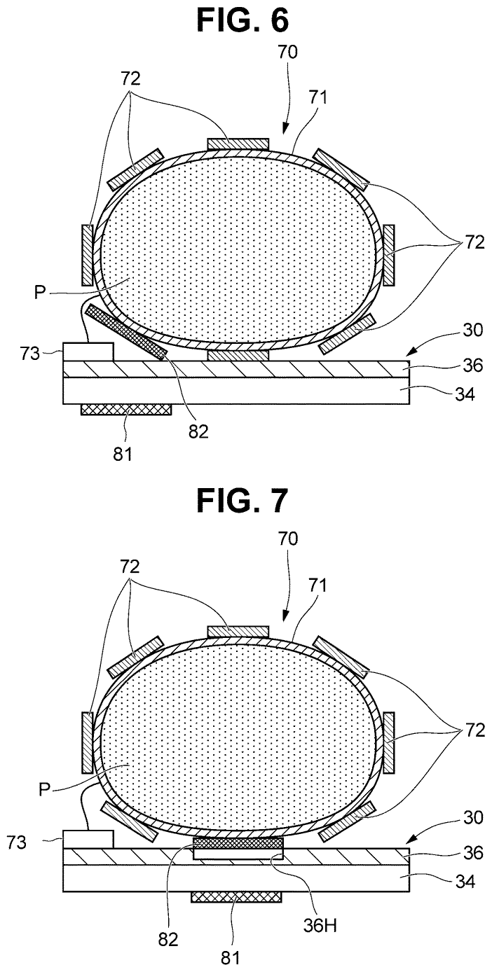

In a case where the position control function 94 determines that the time limit has elapsed (YES in step S117), it is considered that, with the subject P in the current posture, the secondary coil 82 is in an unfavorable position and is in a state where effective power supply from the primary coil 81 to the secondary coil 82 is difficult. FIG. 6 is a schematic cross-sectional view illustrating another state where the subject P is fitted with the RF coil device 70. In this example, a state where the secondary coil 82 is in an unfavorable position is illustrated.

For example, in a case where a gap is generated between the secondary coil 82 and the couchtop 34 while the posture of the subject P is being adjusted, a sufficient coupling coefficient may not be obtained even if the primary coil 81 is moved to the position closest to the secondary coil 82. In this case, in step S119, the notification function 96 issues an instruction for resetting (readjusting) the posture of the subject P to the user as a notification of the setting of the posture of the subject P. As the instruction for resetting, a message prompting a resetting may be displayed on the display device 64 or the like or may be output as audio from a speaker or the like, or information prompting a resetting may be transmitted to the user's terminal device. Subsequently, after the user gives an instruction to start imaging again, the processing in step S101 and subsequent steps is executed.

In a case where the user performs the resetting of the posture of the subject P, the primary current value may be displayed in a manner visible to the user. By viewing the primary current value, the user can easily grasp how much the secondary coil 82 is deviated. As a result, it is possible to make the user easily adjust the posture of the subject P. Accordingly, the processing illustrated in FIG. 5 ends.

The MRI apparatus 1 according to the first embodiment brings the primary coil 81 close to the secondary coil 82 based on the indoor image captured by the camera 85. Then, the MRI apparatus 1 brings the primary coil 81 close to the secondary coil 82 based on the primary current value measured by the ammeter 84. Thus, even if an image of the primary coil 81 is not captured by the camera 85, it is possible to move the primary coil 81 to a position at which the coupling coefficient with respect to the secondary coil 82 can become large. As a result, it is possible to effectively prepare for power supply from the primary coil 81 to the secondary coil 82.

In the first embodiment, for example, a recess (depression) or the like serving as a mark for an installation position of the secondary coil 82 may be provided in the pad 36 laid on the couchtop 34. FIG. 7 is a schematic cross-sectional view illustrating another state where the subject P is fitted with the RF coil device 70. An example in which a recess 36H is provided in the pad 36 is illustrated.

In this example, the recess 36H is a groove in a longitudinal direction of the pad 36 in a rectangular shape in a plan view, and is formed at the substantially center of the pad 36 in a width direction. For example, in a case where the imaging site of the subject P is the lower back and the secondary coil 82 is desired to be installed at the center position of the couchtop 34 in the width direction, the recess 36H that is formed makes it possible to easily install the secondary coil 82 in an appropriate position. Furthermore, since it is possible to increase the coupling coefficient, it is possible to increase the power supply efficiency accordingly.

The recess provided in the pad 36 may be provided at another position. In particular, the recess may be provided according to the imaging site. For example, in a case where an image of the chest of the subject P is to be captured, the recess may be provided in a range corresponding to the upper body of the subject P, and in a case where an image of a limb of the subject P is to be captured, the recess may be provided in a range corresponding to the lower body of the subject P. The recess may be provided in a position other than the center of the couchtop 34 in the width direction, and may be formed in a circular shape or the like in a plan view. The number of locations in the pad 36 in which the recess is provided is not limited to one, and recesses may be provided in a plurality of locations.

While the pad 36 is laid on the couchtop 34 in the first embodiment, there may be a case where the subject P is directly placed on the couchtop 34 without the pad 36 or the like being laid. In consideration of such a case, a recess similar to that provided in the pad 36 laid on the couchtop 34 may be provided in the couchtop 34.

### Second Embodiment

Subsequently, a second embodiment is described. An MRI apparatus according to the second embodiment is mainly different from the first embodiment in that a plurality of primary coils is provided. The MRI apparatus according to the second embodiment is described by focusing on differences from the first embodiment. In the following embodiments, a description of a configuration and an element that are identical to those in the first embodiment may be omitted.

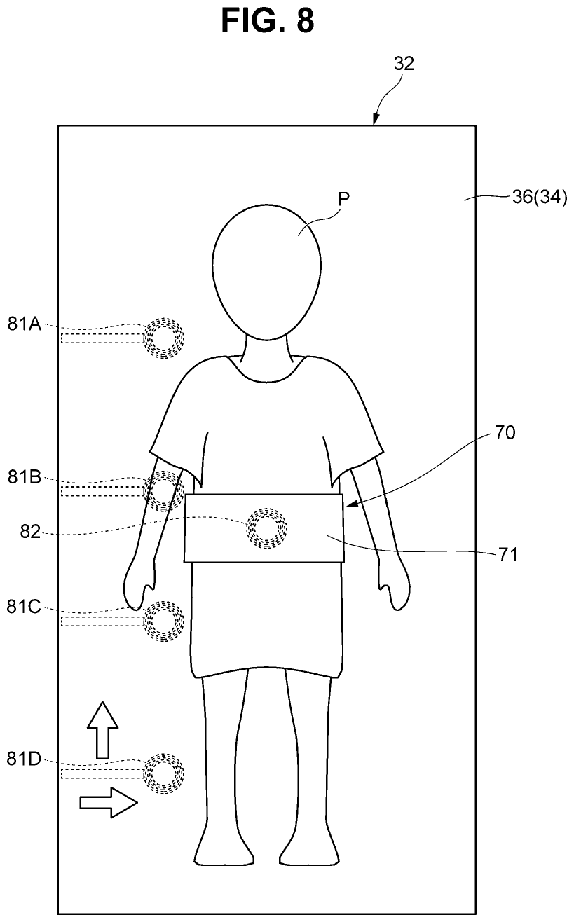

FIG. 8 is a schematic plan view illustrating the subject P fitted with the RF coil device 70 according to the second embodiment. In the MRI apparatus according to the second embodiment, the couchtop 34 of the couch 32 is provided with a first primary coil 81A to a fourth primary coil 81D. The first primary coil 81A to the fourth primary coil 81D each has a configuration similar to that of the primary coil 81 according to the first embodiment.

The conveyance mechanism 83 is capable of conveying the first primary coil 81A to the fourth primary coil 81D independently in both the width direction and the longitudinal direction of the couchtop 34. The coil driving control unit 90 identifies, among the first primary coil 81A to the fourth primary coil 81D, a primary coil that is located closest to the secondary coil 82 (hereinafter referred to as an identified primary coil) based on an indoor image transmitted from the camera 85. When the identified primary coil is in a control range, the coil driving control unit 90 uses the position control function 94 to control the position of the identified primary coil.

The MRI apparatus according to the second embodiment provides actions and effects similar to those provided by the MRI apparatus according to the first embodiment. Further, the MRI apparatus according to the second embodiment is provided with the first primary coil 81A to the fourth primary coil 81D. Thus, since it is possible to supply power to the secondary coil 82 with the primary coil located closest to the secondary coil 82 serving as the identified primary coil, it is possible to expedite power supply to the secondary coil 82 and further expedite the start of capturing an MR image.

### Third Embodiment

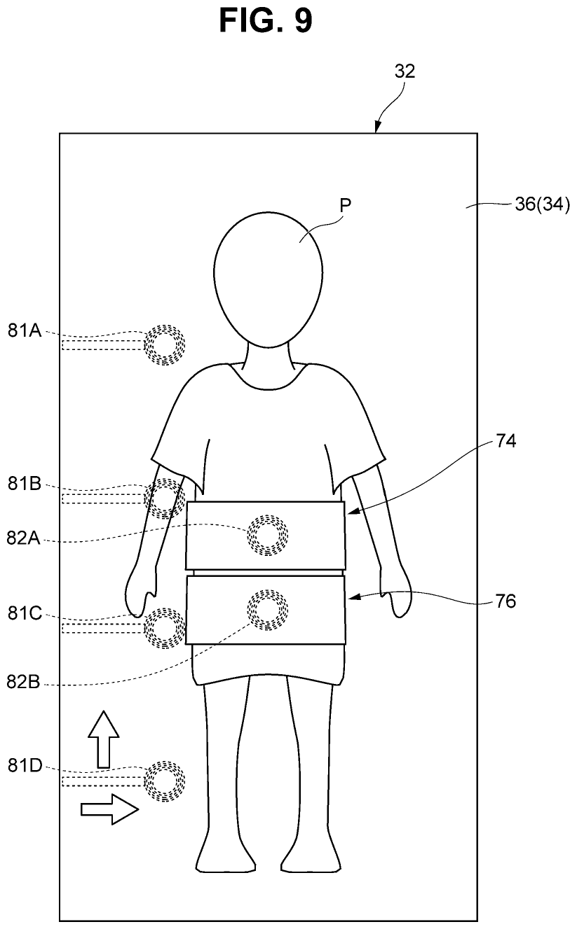

Subsequently, a third embodiment is described. An MRI apparatus according to the third embodiment is mainly different from the first embodiment in that a plurality of primary coils and a plurality of secondary coils are provided. FIG. 9 is a schematic plan view illustrating the subject P fitted with the RF coil device 70 according to the third embodiment.

In the third embodiment, similarly to the second embodiment, the couchtop 34 of the couch 32 is provided with the first primary coil 81A to the fourth primary coil 81D. The subject P is fitted with a chest RF coil device 74 and a lower back RF coil device 76. The chest RF coil device 74 and the lower back RF coil device 76 are provided with a first secondary coil 82A and a second secondary coil 82B, respectively. In the third embodiment, power transmitted from some of the first primary coil 81A to the fourth primary coil 81D, i.e., two of the first primary coils in this case, is simultaneously supplied to a plurality of secondary coils, i.e., two secondary coils in this case, that are the first secondary coil 82A and the second secondary coil 82B.

The conveyance mechanism 83 is capable of conveying the first primary coil 81A to the fourth primary coil 81D independently in both the width direction and the longitudinal direction of the couchtop 34. The coil driving control unit 90 extracts the first primary coil 81A to the fourth primary coil 81D based on the indoor image transmitted from the camera 85.

The coil driving control unit 90 identifies the primary coil (first identified primary coil) 81A that is located closest to the first secondary coil (first identified secondary coil) 82A and the primary coil (second identified primary coil) 81B that is located closest to the second secondary coil (second identified secondary coil) 82B. In a case where the first identified primary coil 81A and the second identified primary coil 81B are in respective control ranges when viewed from the first identified secondary coil 82A and the second identified secondary coil 82B, respectively, the coil driving control unit 90 uses the position control function 94 to control the positions of the first identified primary coil 81A and the second identified primary coil 81B.

The MRI apparatus according to the third embodiment provides actions and effects similar to those provided by the MRI apparatus according to the first embodiment. Further, the MRI apparatus according to the third embodiment is provided with the first primary coil 81A to the fourth primary coil 81D in a state where the subject P is fitted with the chest RF coil device 74 and the lower back RF coil device 76. It is possible to simultaneously supply power from the first identified primary coil and the second identified primary coil among the first primary coil 81A to the fourth primary coil 81D to the first secondary coil 82A and the second secondary coil 82B.

### Fourth Embodiment

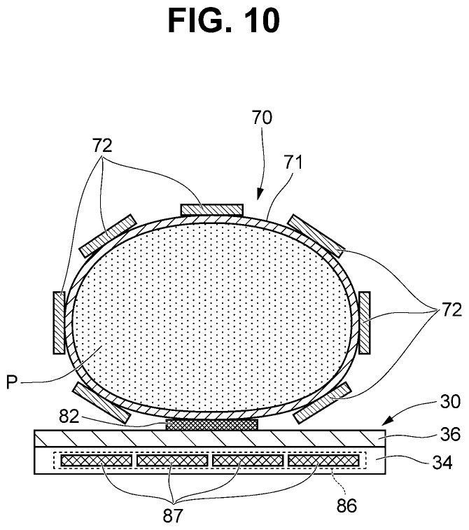

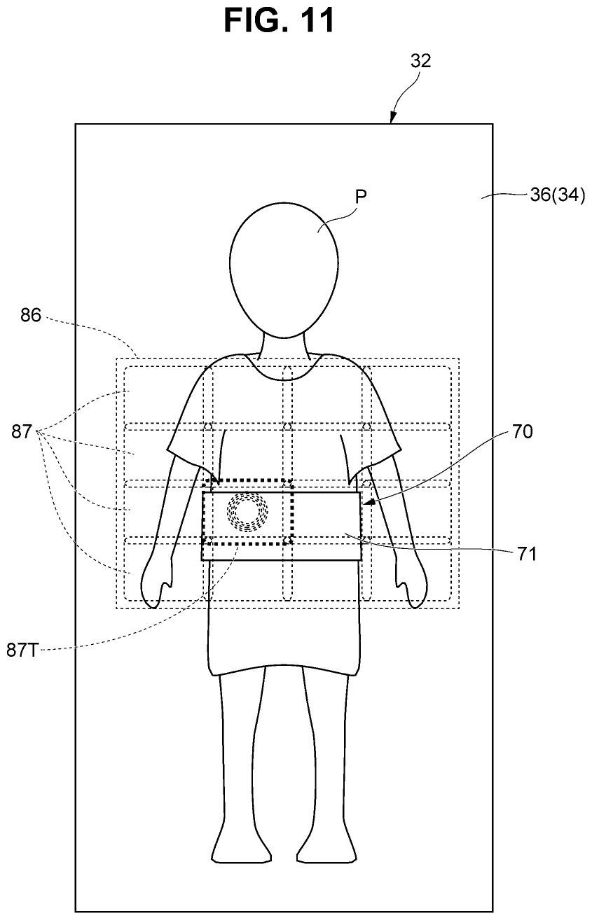

Subsequently, a fourth embodiment is described. An MRI apparatus according to the fourth embodiment is mainly different from the first embodiment in that a spine coil is used as a primary coil. FIG. 10 is a schematic cross-sectional view illustrating a state where the subject P is fitted with the RF coil device 70 according to the fourth embodiment. FIG. 11 is a schematic plan view illustrating the subject P fitted with the RF coil device 70 according to the fourth embodiment.

In the fourth embodiment, the couchtop 34 of the couch 32 is provided with a spine coil 86. In the spine coil 86, a plurality of loops 87 is formed. The loops 87 are arrayed in a matrix in a vertical direction and a horizontal direction in a plan view. One of the plurality of loops 87 (hereinafter referred to as a target loop) functions as the primary coil, and supplies power to the secondary coil 82.

In the fourth embodiment, the ammeter 84, for example, measures a current value of a current flowing in each of the plurality of loops 87 in the spine coil 86, and transmits the current value to the coil driving control unit 90. The coil driving control unit 90 uses the position acquisition function 93 to identify, for example, a loop 87 having the largest primary current value as the target loop based on current values of the plurality of loops 87 measured by the ammeter 84.

The position control function 94 of the coil driving control unit 90 includes, for example, a frequency conversion function that converts frequencies of the plurality of loops 87 in the spine coil 86. The frequency conversion function is a function of converting a frequency of an identified loop 87T among the plurality of loops 87 in the spine coil 86 into a frequency for power transmission and a frequency for signal reception using dual resonance, and converting frequencies of loops 87 other than the identified loop 87T into frequencies for signal reception. The position control function 94, by converting the frequencies of the plurality of loops 87, controls the position of the identified loop 87T that functions as a power transmission coil. The frequency conversion function is an example of a frequency conversion unit.

The MRI apparatus according to the fourth embodiment provides actions and effects similar to those provided by the MRI apparatus according to the first embodiment. Further, in the MRI apparatus according to the fourth embodiment, the couchtop 34 is provided with the spine coil 86, and the frequency of the identified loop 87T with the large primary current value among the plurality of loops 87 included in the spine coil 86 is converted into the frequency for power transmission, which allows the spine coil 86 to function as the power transmission coil. As a result, there is no need for the conveyance mechanism 83 that moves the primary coil 81, which makes it possible to simplify the MRI apparatus accordingly.

According to at least one of the above-mentioned embodiments, a magnetic resonance imaging apparatus includes a couch device including a couchtop on which a subject is placed, a power transmission coil provided in the couch device and configured to wirelessly transmit power to a power reception coil provided in a reception coil unit including a reception coil, the reception coil unit being attached to the subject placed on the couchtop, the reception coil being configured to detect a magnetic resonance signal generated from the subject, a detection unit configured to detect a current flowing in the power transmission coil, a movement mechanism configured to move the power transmission coil, and a control unit configured to control the movement mechanism based on a current value detected by the detection unit in a state where a voltage is applied to the power transmission coil. The magnetic resonance signal detected by the reception coil is transmitted based on the power wirelessly transmitted from the power transmission coil to the power reception coil. As a result, it is possible to effectively prepare for power supply.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a couch device including a couchtop on which a subject is placed;
a power transmission coil provided in the couch device and configured to wirelessly transmit power to a power reception coil provided in a reception coil unit including a reception coil, the reception coil unit being attached to the subject placed on the couchtop, the reception coil being configured to detect a magnetic resonance signal generated from the subject;
a detection unit configured to detect a current flowing in the power transmission coil;
a movement mechanism configured to move the power transmission coil; and
a control unit configured to control the movement mechanism based on a current value detected by the detection unit in a state where a voltage is applied to the power transmission coil,
wherein the magnetic resonance signal detected by the reception coil is transmitted based on the power wirelessly transmitted from the power transmission coil to the power reception coil.

2. The magnetic resonance imaging apparatus according to claim 1, wherein the control unit is configured to control the movement mechanism such that the power transmission coil is located at a position where the current value detected by the detection unit in the state where a voltage is applied to the power transmission coil is greater than a predetermined value.

3. The magnetic resonance imaging apparatus according to claim 2,
wherein the control unit is configured to control the movement mechanism, based on an image obtained by a camera configured to capture an image of the couchtop, such that a distance between the power transmission coil and the reception coil unit is equal to or less than a predetermined distance, and
wherein, in a state where the distance between the power transmission coil and the reception coil unit is equal to or less than the predetermined distance, the control unit is configured to control the movement mechanism such that the power transmission coil is located at the position where the current value detected by the detection unit in the state where a voltage is applied to the power transmission coil is greater than the predetermined value.

4. The magnetic resonance imaging apparatus according to claim 1, further comprising a notification unit configured to, when a state where the current value detected by the detection unit in the state where a voltage is applied to the power transmission coil is less than the predetermined value continues for a predetermined time, issue a notification indicating that a setting of the reception coil unit for the subject is to be performed.

5. The magnetic resonance imaging apparatus according to claim 1, wherein the power transmission coil is provided on an opposite side of the subject with respect to the couchtop.

6. The magnetic resonance imaging apparatus according to claim 1, wherein the magnetic resonance signal detected by the reception coil is transmitted via wireless communication based on the power wirelessly transmitted from the power transmission coil to the power reception coil.

7. A magnetic resonance imaging apparatus comprising:
a couch device including a couchtop on which a subject is placed;
a power transmission coil provided in the couch device and configured to wirelessly transmit power to a power reception coil provided in a reception coil unit including a spine coil as a reception coil, the spine coil including a plurality of loops each configured to detect a magnetic resonance signal generated from the subject;
a detection unit configured to detect a current flowing in the power transmission coil;
a movement mechanism configured to move the power transmission coil; and
a control unit configured to control the movement mechanism based on a current value detected by the detection unit in a state where a voltage is applied to the power transmission coil,
wherein the magnetic resonance signal detected by the reception coil is transmitted based on the power wirelessly transmitted from the power transmission coil to the power reception coil.
